(19) United States
(12) Patent Application Publication
(10) Pub. No.: US 2024/0178148 A1
(43) Pub. Date: May 30, 2024

(54) ETCH-BACK OPENING WITH PROTECTIVE FILL STRUCTURE

(71) Applicant: Micron Technology, Inc., Boise, ID (US)

(72) Inventors: Kimball Davis LOWRY, Boise, ID (US); Avishesh DHAKAL, Meridian, ID (US)

(21) Appl. No.: 18/497,559

(22) Filed: Oct. 30, 2023

Related U.S. Application Data
(60) Provisional application No. 63/385,564, filed on Nov. 30, 2022.

(51) Int. Cl. H01L 23/538; H01L 25/065; H10B 80/00

(52) U.S. Cl. CPC H01L 23/5386; H01L 23/5383; H01L 25/0652; H10B 80/00; H01L 2225/06562

(57) ABSTRACT

Implementations described herein relate to a semiconductor substrate assembly and methods of manufacturing. The substrate assembly may include a top insulator layer and a conductive layer below the top insulator layer. The conductive layer may include an end of a conductive structure. The substrate assembly may include a bottom insulator layer below the conductive layer. The substrate assembly may include a protective fill structure. The protective fill structure may be adjacent to the end of the conductive structure and pass at least partially through the top insulator layer to the bottom insulator layer.

### CROSS-REFERENCE TO RELATED APPLICATION

This patent application claims priority to U.S. Provisional Patent Application No. 63/385,564, filed on Nov. 30, 2022, entitled “ETCH-BACK OPENING WITH PROTECTIVE FILL STRUCTURE,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to an etch-back opening with a protective fill structure.

### BACKGROUND

A semiconductor package includes a casing that contains one or more semiconductor devices, such as integrated circuits. Semiconductor device components may be fabricated on semiconductor wafers before being diced into die and then packaged. A semiconductor package protects internal components from damage and includes means for connecting internal components to external components (e.g., a circuit board), such as via balls, pins, or leads. A semiconductor device assembly may be or may include a semiconductor package or one or more components of a semiconductor package (e.g., one or more semiconductor devices with or without a casing).

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIGS. 3A-3E are diagrams of an example series of operations that includes forming a substrate including a protective fill structure described herein.

FIGS. 4A, 4B, and 5 are diagrams of example implementations of a substrate including a protective fill structure described herein.

FIG. 6 is a diagram of an example implementation of a conductive layer described herein.

FIG. 7A are 7B diagrams of example implementations of a test interface substrate formed using techniques described herein.

FIG. 8 is a flowchart of an example method of forming a substrate having a protective fill structure.

FIG. 9 is a flowchart of an example method of forming an integrated assembly or apparatus including a substrate having a protective fill structure.

### DETAILED DESCRIPTION

In some cases, a semiconductor device assembly includes a semiconductor device (e.g., an integrated circuit or a semiconductor die) coupled to a substrate assembly. The substrate assembly may include one or more insulator layers interspersed with one or more conductive layers. The one or more conductive layers may each include one or more conductive structures (e.g., a circuit structure, such as a ground plane structure, a power plane structure, a data transmission structure, and/or a clocking structure). In some implementations, the one or more conductive structures are coupled to the semiconductor device.

Formation of the substrate assembly may include using a plating operation to form a conductive layer (including the conductive structures) above an insulator layer. To facilitate the plating operation, two or more of the conductive structures may be electrically coupled via electrical traces. After formation of one or more additional layers over the conductive layer (e.g., an insulator layer, a conductive layer, and/or a solder resist layer) and prior to completing formation of the substrate assembly, an etch-back operation may be performed. The etch-back operation may be performed to decouple (e.g., electrically isolate) the two or more conductive structures by severing the electrical traces to enable functionality of the substrate assembly. Additionally, or alternatively, the etch-back operation may reduce a length of a plating stub and improve a performance of the substrate assembly (e.g., reduce a ring-back noise to improve signal integrity).

Several byproducts may be formed as a result of the etch-back operation. For example, the etch-back operation may form ends (e.g., terminated ends or stubs) of the conductive structures (e.g., the electrical traces). Additionally, or alternatively, the etch-back operation may form an etch-back opening that exposes the ends of the conductive structures to environmental conditions surrounding the substrate assembly. In some cases, exposure of the ends of the conductive structures to the environmental conditions increases a likelihood of a contaminant gathering and bridging (e.g., electrically connecting) the ends of the conductive structures. In such cases, a likelihood of electrical shorting within the substrate assembly may increase, resulting in malfunction of the semiconductor device.

Furthermore, exposure of the ends of the conductive structures may increase a likelihood of an electrostatic discharge (ESD) to the ends of the conductive structures. In such cases, a likelihood of ESD damage to the conductive structures that renders the conductive structures inoperable may increase. Still further, exposure of the ends of the conductive structures may increase a likelihood of oxidation and/or corrosion to the ends of the conductive structures. In such cases, a likelihood of circuitry defects (e.g., an electrical resistance and/or an electrical capacitance) within the substrate assembly may increase. Also, the etch-back opening may decrease a rigidity of the substrate assembly and increase a likelihood of a flexure of the substrate assembly (e.g., a flexure during reliability testing of a semiconductor device assembly including the substrate and/or a field use of a semiconductor device assembly including the substrate assembly). In such cases, a likelihood of cracking of electrical traces or dielectric layers within the substrate assembly may increase.

Some implementations described herein provide a substrate assembly and methods of formation. The substrate assembly may include a top insulator layer and a conductive layer below the top insulator layer. The conductive layer may include an end of a conductive structure. The substrate assembly may include a bottom insulator layer below the conductive layer. The substrate assembly may include a protective fill structure. The protective fill structure may be adjacent to the end of the conductive structure and pass at least partially through the top insulator layer to the bottom insulator layer.

The protective fill structure may prevent a contaminant from gathering and bridging the end of the conductive structure to another conductive structure, thereby reducing a likelihood of electrical shorting within the substrate assembly. Additionally, or alternatively, the protective fill structure may insulate the end of the conductive structures, thereby reducing a likelihood of ESD damage to the conductive structure. Additionally, or alternatively, the protective fill structure may protect the end of the conductive structure from oxidation and/or corrosion, thereby reducing a likelihood of circuitry defects within the substrate assembly. Additionally, or alternatively, the protective fill structure may increase a rigidity of the substrate assembly, thereby reducing a likelihood of a flexure of the substrate assembly that causes cracking of electrical traces or dielectric layers within the substrate assembly.

In this way, a manufacturing yield of the semiconductor device assembly including the substrate assembly may increase relative to another semiconductor device assembly that does not include the substrate assembly. Furthermore, a field failure rate of the semiconductor device assembly may decrease relative to another semiconductor device assembly that does not include the substrate assembly. By increasing the manufacturing yield and decreasing the field failure rate, an amount of resources to fabricate and sustain a volume of the semiconductor device assembly (e.g., an amount of semiconductor manufacturing tools, raw materials, manpower, and/or computing resources) may be decreased and/or reallocated to manufacturing of other semiconductor device assemblies.

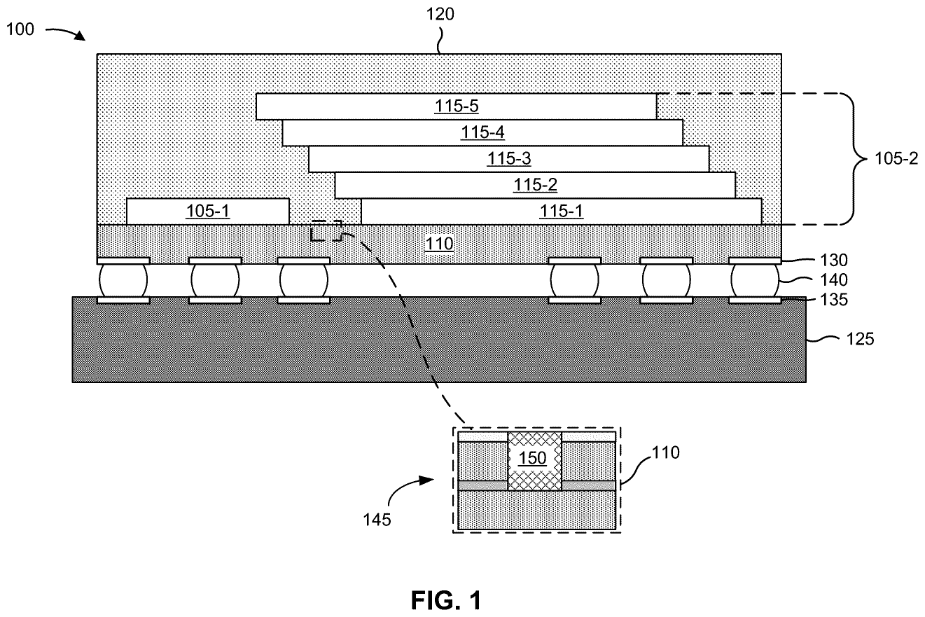

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include multiple semiconductor dies 115 (sometimes called dies), shown as five semiconductor dies 115-1 through 115-5. As shown in FIG. 1, the dies 115 may be stacked on top of each other to reduce a footprint of the apparatus 100. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

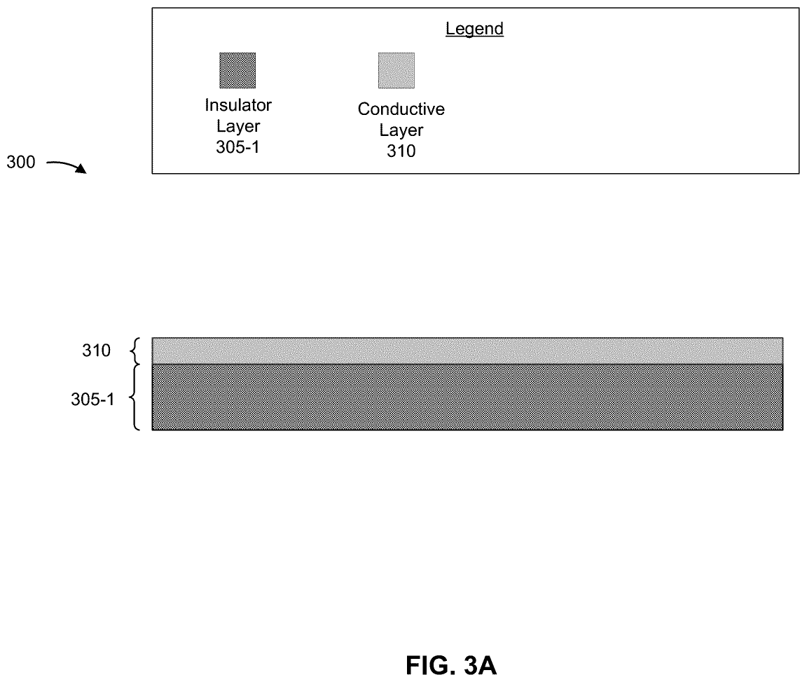

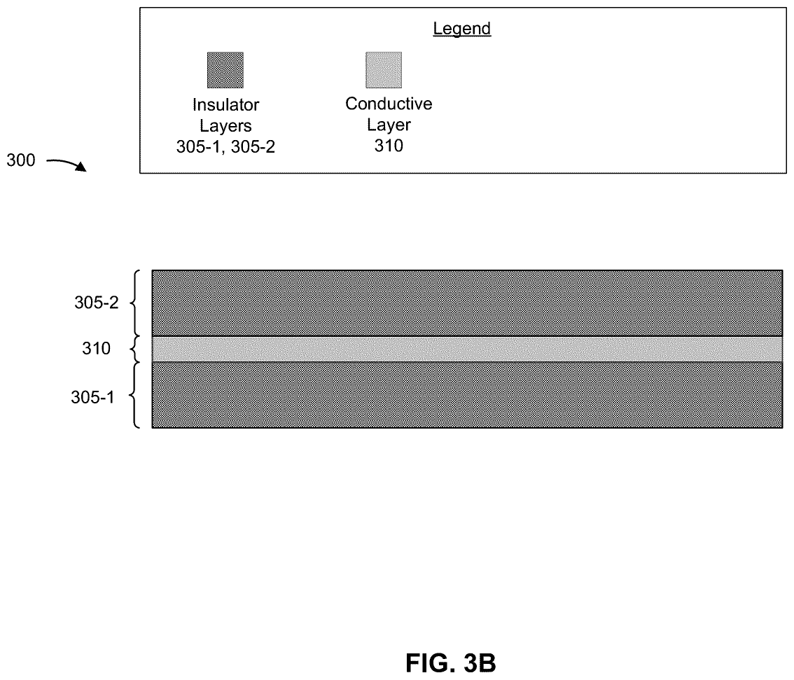

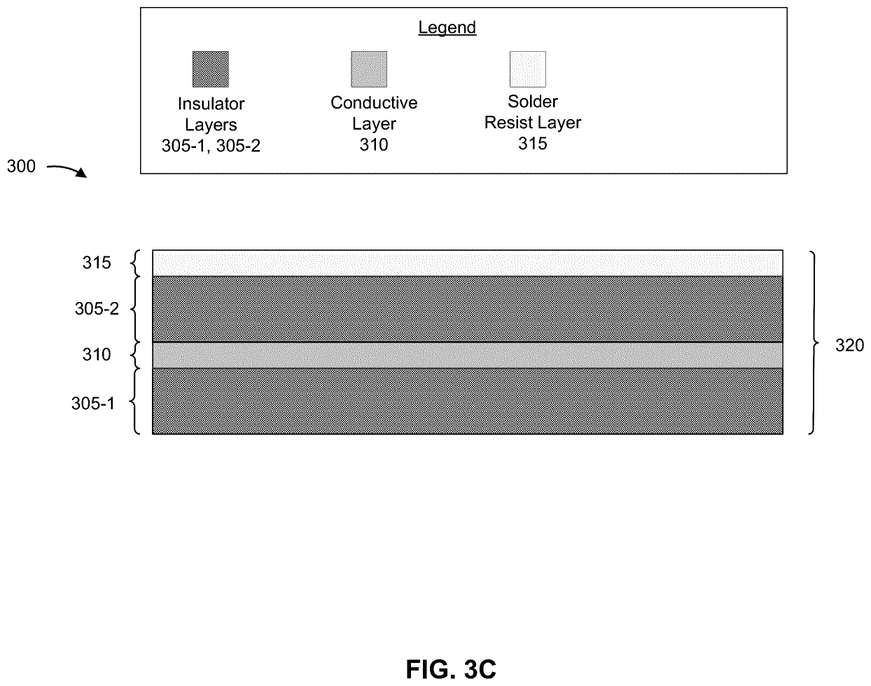

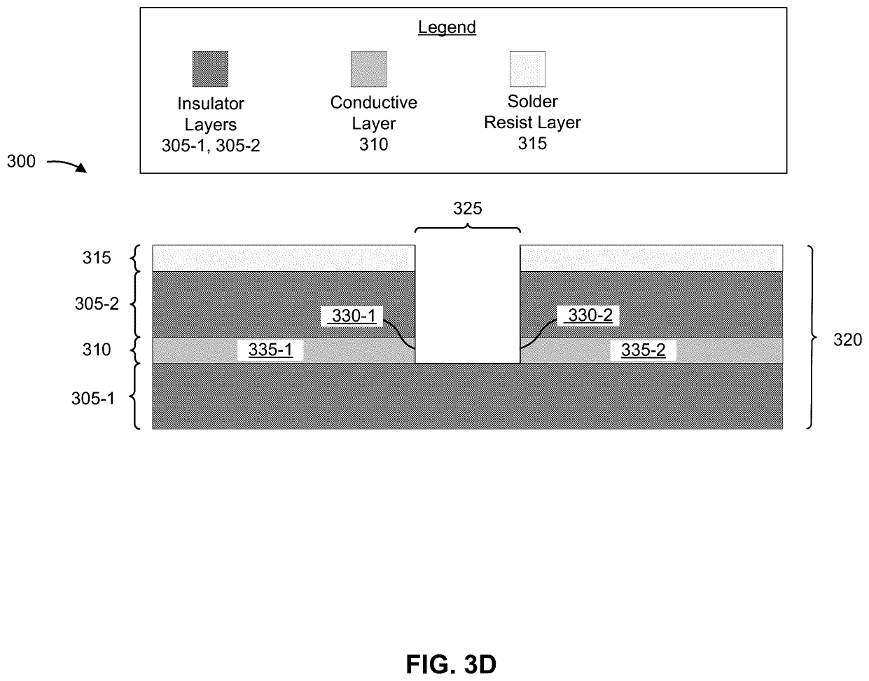

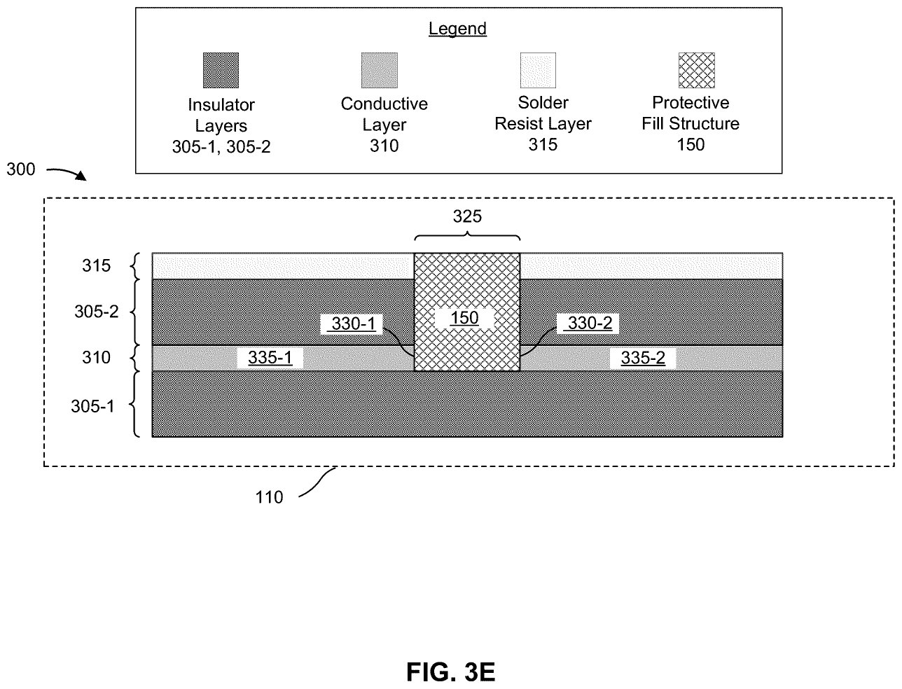

FIG. 1 further shows an example magnified view 145 of the substrate 110. In some implementations, and as described in greater detail in connection with FIGS. 3A-3E, 4A-4B, 5, and elsewhere herein, the substrate 110 includes a protective fill structure 150. The protective fill structure 150 may be formed in the substrate 110 after an etch-back operation. The protective fill structure 150 may prevent a contaminant from bridging between conductive structures (e.g., circuitry) included in the substrate 110. Additionally, or alternatively, the protective fill structure 150 may protect ends of the conductive structures from oxidation and/or corrosion. Additionally, or alternatively, the protective fill structure 150 may increase a rigidity of the substrate 110 (and/or the apparatus 100).

As indicated above, FIG. 1 is provided as an example. Other examples may differ from what is described with regard to FIG. 1.

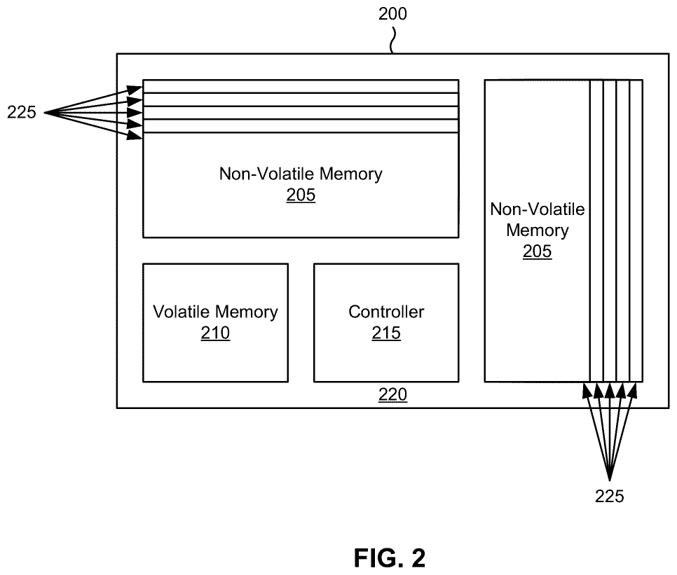

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIGS. 3A-3E are diagrams of an example series of operations 300 that includes forming the substrate 110 including the protective fill structure 150 described herein. As described in greater detail in connection with FIGS. 3A-3E and elsewhere herein, the series of operations 300 may include performing an etch-back operation to form an opening (e.g., an etch-back opening) in the substrate 110.

As shown in FIG. 3A, the series of operations 300 may include forming an insulator layer 305-1 (e.g., a first insulator layer or a bottom insulator layer) and forming a conductive layer 310 on the insulator layer 305-1. In some implementations, the insulator layer 305-1 includes an organic, dielectric material, such as a glass-reinforced epoxy laminate material, among other examples.

The conductive layer 310 may include a conductive material, such as a copper (Cu) material, an aluminum (Al) material, a gold (Au) material, or a silver (Ag) material, among other examples. As an example, forming the conductive layer 310 on the insulator layer 305-1 may include using a semiconductor plating tool to form the conductive layer 310 using a plating operation. In some implementations, the conductive layer 310 includes one or more conductive structures (e.g., circuit structures, such as a ground plane structure, a power plane structure, a clocking structure, or a data transmission structure). To facilitate the plating operation, the conductive structures may be electrically connected via trace structures, plating bus structures, or the like.

As shown in FIG. 3B, the series of operations 300 may include forming an insulator layer 305-2 (e.g., a second insulator layer or a top insulator layer) on the conductive layer 310. In some implementations, the insulator layer 305-2 includes an organic, dielectric material, such as a glass-reinforced epoxy laminate material, among other examples. As an example, forming the insulator layer 305-2 on the conductive layer 310 may include using a semiconductor laminating tool to perform a lamination operation that joins the insulator layer 305-2 and the conductive layer 310.

As shown in FIG. 3C, the series of operations 300 may include forming a solder resist layer 315 on the insulator layer 305-2. The solder resist layer 315 may include a polymer material that provides protection against oxidation and/or corrosion to portions of a substrate (e.g., the substrate 110) that include the insulator layer 305-1, the conductive layer 310, and the insulator layer 305-2.

As an example, forming the solder resist layer 315 may include using a semiconductor printing tool to perform a silk screening technique to form the solder resist layer 315 on the insulator layer 305-2. In some implementations, the insulator layer 305-1, the conductive layer 310, the insulator layer 305-2, and the solder resist layer 315 combine to form a layer stack 320.

As shown in FIG. 3D, the series of operations 300 may include forming an isolation region 325 that passes through the solder resist layer 315, through the insulator layer 305-2, and through the conductive layer 310. The isolation region 325 (e.g., an “etch-back opening”) may be formed through the conductive layer 310 and to the insulator layer 305-1 (e.g., a top surface of the insulator layer 305-1). Furthermore, the series of operations 300 may include forming the isolation region 325 so that the isolation region 325 extends partially into the insulator layer 305-2 or through the insulator layer 305-2.

As an example, forming the isolation region 325 may include using a semiconductor etch tool to form the isolation region 325 using an acid-based etchant to perform an etch-back operation. Additionally, or alternatively, forming the isolation region 325 may include using a semiconductor laser tool to form the isolation region 325 using an ablation operation.

The isolation region 325 may decouple (e.g., electrically isolate) a conductive structure 335-1 (e.g., a first conductive structure) from a conductive structure 335-2 (e.g., a second conductive structure). The conductive structure 335-1 and/or the conductive structure 335-2 may be or may include a circuit structure, such as a ground plane structure, a power plane structure, a data transmission structure, or a signaling structure.

A further shown in FIG. 3D, the isolation region 325 exposes an end 330-1 (e.g., a first terminated end or a first stub) of the conductive structure 335-1. Additionally, or alternatively, the isolation region 325 may expose an end 330-2 (e.g., a second terminated end or a second stub) of the conductive structure 335-2.

Due to exposure of the ends 330-1 and 330-2, the conductive structures 335-1 and 335-2 may be subject to a risk of ESD damage. Additionally, or alternatively, due to exposure, the ends 330-1 and 330-2 may be subject to a risk of contamination that electrically couples the ends 330-1 and 330-2 (e.g., causes an electrical short between the conductive structures 335-1 and 335-2). Additionally, or alternatively, due to exposure, the ends 330-1 and 330-2 may be subject to a risk of corrosion or oxidation. Further, and due to a presence of the isolation region 325, the layer stack 320 may be subject to a risk of a rigidity of the layer stack 320 (e.g., the substrate 110) not satisfying a threshold.

As shown in FIG. 3E, the series of operations 300 may include forming the protective fill structure 150. The protective fill structure 150 may include a fill material (e.g., a polymer material with dielectric properties) that mitigates risks related to the presence of the isolation region 325 and the exposure of the ends 330-1 and 330-2, such as risks described above.

As an example, forming the protective fill structure 150 may include using a semiconductor printing tool to perform a screen printing operation that screen prints the fill material into the isolation region 325. Additionally, or alternatively, forming the protective fill structure 150 may include using a semiconductor dispense tool to dispense an epoxy material (e.g., including the polymer material) into the isolation region 325 and using a semiconductor curing tool to perform a curing operation that hardens the epoxy material. Additionally, or alternatively, forming the protective fill structure 150 may include using a semiconductor reflow tool to perform a reflow operation (e.g., a heating operation) to cause the solder resist layer 315 (e.g., including the polymer material) to liquefy and flow into the isolation region 325. In this case, and in some implementations, a material of the solder resist layer 315 may be the same as the fill material of the protective fill structure 150. Additionally, or alternatively, forming the protective fill structure 150 may include using a semiconductor plugging tool to perform a plugging operation that fills (e.g., plugs) the isolation region 325 with a preformed rendering of the protective fill structure 150. In some implementations, a material of the solder resist layer 315 is different from the fill material of the protective fill structure 150.

In some implementations, and as shown in FIG. 3E, the protective fill structure 150 passes entirely through the solder resist layer 315 and the insulator layer 305-2 (e.g., the protective fill structure 150 occupies an entire volume of the isolation region 325). In some implementations, the protective fill structure 150 passes at least partially through the insulator layer 305-2. “Passing at least partially through” means passing partially through or passing entirely through. Thus, the protective fill structure 150 may occupy a portion of a volume of the isolation region 325 or may occupy all of the volume of the isolation region 325. For example, the protective fill structure 150 may fill a portion of the isolation region 325 adjacent to the first end 330-1 and/or adjacent to the second end 330-2, and may fill either all or part of the remaining portion of the isolation region 325 (e.g., up to a top surface of the insulator layer 305-2 or up to a top surface of the solder resist layer 315). Thus, the protective fill structure 150 may be in contact with the conductive structure 335-1 (e.g., at the end 330-1) and/or may be in contact with the conductive structure 335-2 (e.g., at the end 330-2).

In some implementations, the protective fill structure 150 may have one or more properties selected so that the rigidity of the substrate 110 satisfies a rigidity threshold. For example, the one or more properties may include a volume of the protective fill structure 150 (e.g., a volume corresponding to a partial volume or an entire volume of the isolation region 325). Additionally, or alternatively, the one or more properties may include a modulus of elasticity of a material included in the protective fill structure 150. Additionally, or alternatively, the one or more properties may include a location of the protective fill structure 150 within the substrate 110 (e.g., a location of the isolation region 325 within the substrate 110). Additionally, or alternatively, the one or more properties may include a cross-sectional shape of the protective fill structure 150 (e.g., a rectangular cross-sectional shape, a diamond cross-sectional shape, a triangular cross-sectional shape, an elliptical cross-sectional shape, or a circular cross-sectional shape). As such, the rigidity of the substrate 110 may be based on the one or more properties.

In some implementations, one or more operations of the series of operations 300 may be applicable to other components described in connection with FIGS. 1 and 2. For example, the printed circuit board 125 and/or the substrate 220 may be fabricated using techniques substantially similar to those shown in and described in connection with FIGS. 3A-3E. Additionally, or alternatively, one or more operations of the series of operations 300 may be applicable in cases where the insulator layer 305-1 and/or the insulator layer 305-2 include an inorganic material (e.g., a silicon material or a ceramic material).

As indicated above, FIGS. 3A-3E are provided as examples. Other examples may differ from what is described with regard to FIGS. 3A-3E. Further, in some implementations the series of operations 300 may include additional operations, fewer operations, different operations, or differently arranged operations than those depicted in FIGS. 3A-3E.

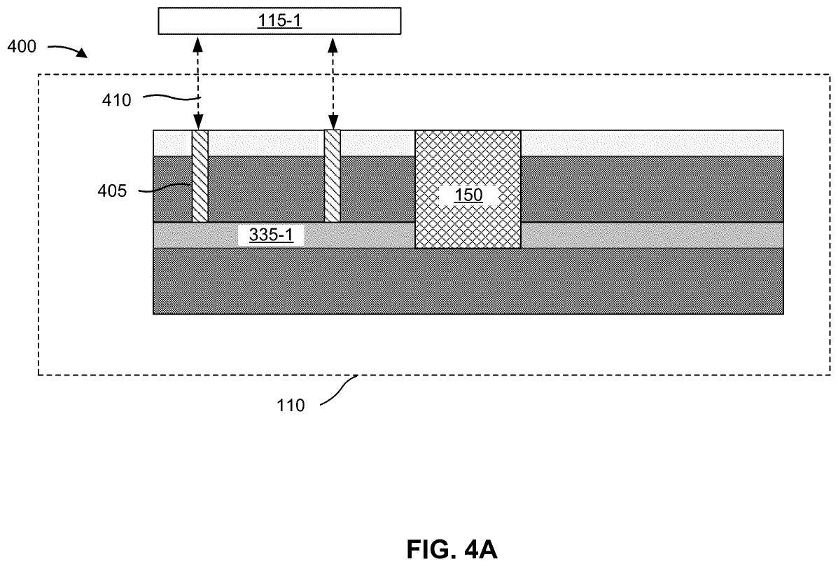

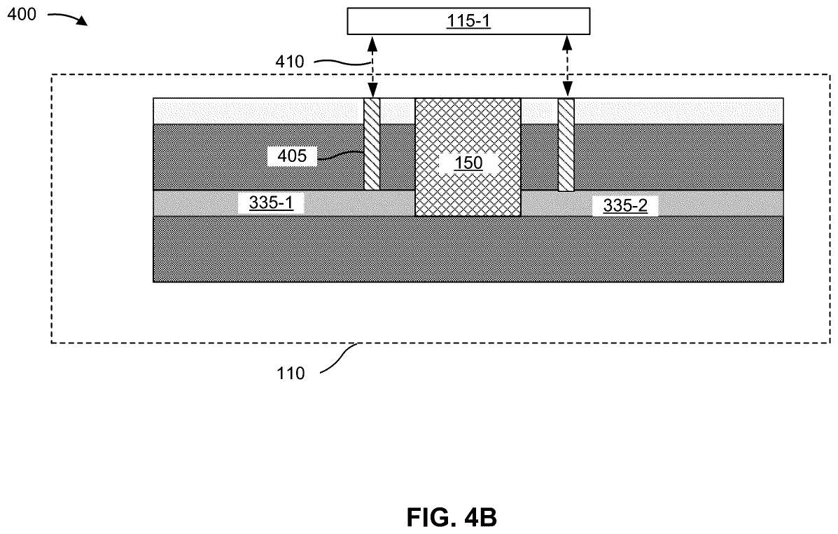

FIGS. 4A and 4B are diagrams of example implementations 400 of the substrate 110 including the protective fill structure 150 described herein. The implementations 400 may correspond to one or more portions of the apparatus 100 of FIG. 1.

As shown in FIG. 4A, in some implementations, the semiconductor die 115-1 is not directly above (e.g., may be adjacent to or offset from) the protective fill structure 150. The semiconductor die 115-1 may not be directly above the protective fill structure 150 due to layout constraints (e.g., routing of electrical traces and/or conductive structures) within the conductive layer 310. Additionally, or alternatively, and as shown in FIG. 4A, the semiconductor die 115-1 may be directly above the conductive structure 335-1 to shorten a signaling path (e.g., to reduce an electrical inductance). The semiconductor die 115-1 may be communicatively coupled to the conductive structure 335-1 using one or more vertical interconnect access (via) structures 405 and/or using one or more connection structures 410 (e.g., a wire bond, a solder ball, a stud, or a bump bond).

As shown in FIG. 4B, in some implementations, the semiconductor die 115-1 is directly above the protective fill structure 150. The semiconductor die 115-1 may be directly above the protective fill structure 150 due to layout constraints (e.g., routing of electrical traces and/or conductive structures) within the conductive layer 310. Additionally, or alternatively, the semiconductor die 115-1 may be directly above the protective fill structure 150 to position the semiconductor die 115-1 above two or more conductive structures within the conductive layer 310. For example, and as shown in FIG. 4B, semiconductor die 115-1 may be communicatively coupled to the conductive structure 335-1 and the conductive structure 335-2 using one or more via structures 405 and/or one or more connection structures 410.

As indicated above, FIGS. 4A and 4B are provided as examples. Other examples may differ from what is described with regard to FIGS. 4A and 4B. Further, the number and arrangement of components shown in FIGS. 4A and 4B are provided as an example. In practice, there may be additional components, fewer components, different components, or differently arranged components than those shown in FIGS. 4A and 4B.

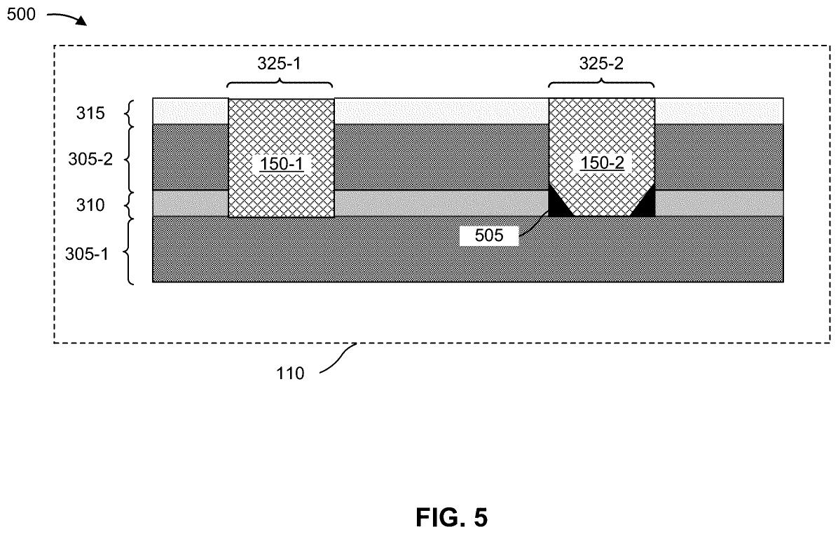

FIG. 5 is a diagram of an example implementation 500 of the substrate 110 including the protective fill structure 150 described herein. As shown in FIG. 5, the substrate 110 includes multiple protective fill structures, including the protective fill structure 150-1 in the isolation region 325-1 and the protective fill structure 150-2 in the isolation region 325-2.

In contrast to the isolation region 335-1, the isolation region 335-2 includes contaminants 505. The contaminants 505 may be remnants of a process (e.g., an etch-back process) used to form the isolation region 325-2. The contaminants 505 may include materials from the solder resist layer 315, the isolation layer 305-2, and/or the conductive layer 310, among other examples.

As shown in FIG. 5, the protective fill structure 150-2 may retain the contaminants 505 and prevent the contaminants 505 from gathering further and/or dislodging to cause a failure in the substrate 110 (e.g., an electrical short). Additionally, or alternatively, the protective fill structure 150-2 may retain the contaminants 505 and prevent the contaminants 505 from gathering further and/or dislodging to cause a failure in an apparatus including the substrate 110 (e.g., an electrical short or a bonding failure of an electrical connection within the apparatus 100).

As indicated above, FIG. 5 is provided as an example. Other examples may differ from what is described with regard to FIG. 5.

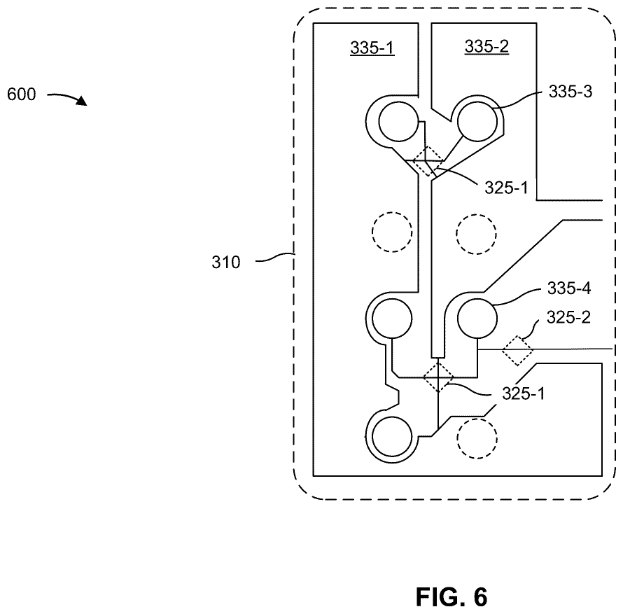

FIG. 6 is a diagram of an example implementation 600 of the conductive layer 310 described herein. FIG. 6 shows an example plan view of example conductive structures (e.g., circuitry) that may be included in the conductive layer 310. A combination of such conductive structures may sometimes be referred to as a “net.” Further, types and combinations of such conductive structures may vary based on a pinout (e.g., a design layout of connection structures) of a corresponding integrated circuit that is coupled to a substrate (e.g., a design layout of wire bond pads or solder bumps for the integrated circuit die 115-1 that is coupled to the substrate 110).

As shown in FIG. 6, the conductive layer 310 may include the conductive structure 335-1, which may correspond to a power plane structure. As further shown in FIG. 6, the conductive layer 310 may include the conductive structure 335-2, which may correspond to a ground plane structure. As further shown in FIG. 6, the conductive layer 310 may include a conductive structure 335-3, which may correspond to a data transmission structure. As further shown in FIG. 6, the conductive layer 310 may include the conductive structure 335-4, which may correspond to a clocking structure.

In some implementations, and for plating purposes, the conductive structures 335-1 through 335-4 are electrically connected by traces during formation of the conductive layer 310. As described in connection with FIG. 3D and elsewhere herein, formation of the isolation region 325-1 (e.g., an etch-back opening) may decouple (e.g., electrically isolate) the conductive structures 335-1 through 335-4 from each other. Additionally, or alternatively, formation of the isolation region 325-2 may reduce a length of a plating stub (e.g., an electrical trace leading to a plating bus) to reduce a ring-back noise and improve signal integrity within a substrate (e.g., the substrate 110) including the conductive layer 310.

As indicated above, FIG. 6 is provided as an example. Other examples may differ from what is described with regard to FIG. 6.

The protective fill structure 150 as described in connection with FIGS. 1-6 may increase an overall performance of the apparatus 100 relative to another apparatus having another substrate not including the protective fill structure 150. For example, the protective fill structure 150 may reduce a likelihood of electrical shorting within the apparatus 100 and/or the substrate 110. Additionally, or alternatively, the protective fill structure 150 may reduce a likelihood of circuitry defects (e.g., electrical resistance and/or electrical capacitance) within the substrate 110. Additionally, or alternatively, the protective fill structure 150 may reduce a likelihood of a flexure of the substrate 110 (e.g., a flexure during a reliability testing of the apparatus and/or a field use of the apparatus 100) that causes cracking of electrical traces within the substrate 110.

In this way, a manufacturing yield of the apparatus 100 may increase and a field failure rate of the apparatus 100 may decrease. By increasing the manufacturing yield and decreasing the field failure rate, an amount of resources to fabricate and sustain a volume of the apparatus 100 (e.g., an amount of semiconductor manufacturing tools, raw materials, manpower, and/or computing resources).

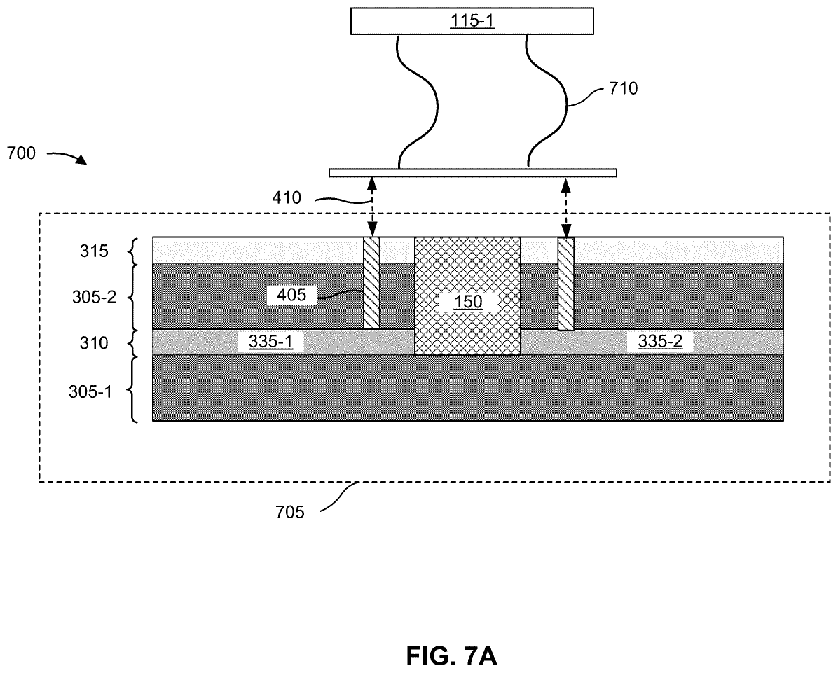

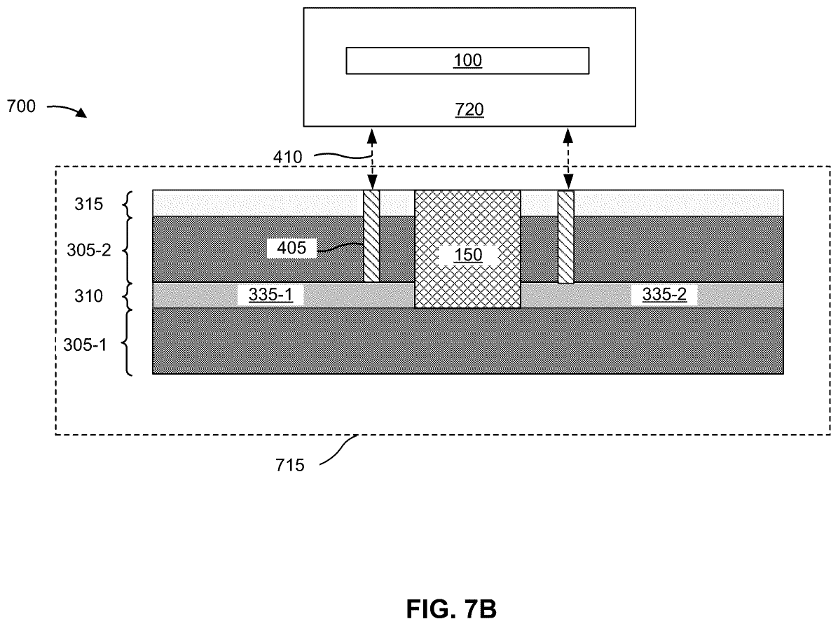

FIG. 7A are 7B diagrams of example implementations 700 of a test interface substrate formed using techniques described herein. The implementations 700 of FIGS. 7A and 7B may be formed using techniques substantially similar to those described in connection with FIGS. 3A-3E, 4A-4B, 5, 6, and elsewhere herein. The implementations 7A and 7B may relate to test interface substrates for different types of automated testing equipment (ATE), including a probe test system to test a performance quality of a semiconductor device (e.g., the semiconductor die 115-1) and/or a burn-in test system to test a reliability of a semiconductor device assembly (e.g., the apparatus 100).

As shown in FIG. 7A, in some implementations, the test interface substrate includes a probe card substrate 705 including the protective fill structure 150. In some implementations, one or more probes 710 (e.g., electrically conductive probe needles, electrically conductive cantilever probe structures, electrically conductive pogo-pin structures, or electrically conductive pillar structures) are communicatively coupled to the probe card substrate 705. The one or more probes 710 may be communicatively coupled to the conductive structure 335-1 and 335-2 using one or more vertical interconnect access (via) structures 405 and/or one or more connection structures 410, among other examples.

In some implementations, the probe card substrate 705 may be communicatively coupled to a probe test system to test a performance quality of the semiconductor die 115-1 (e.g., a signaling quality, a timing/speed quality, and/or or a parametric quality). In some implementations, testing the performance quality of the semiconductor die 115-1 includes testing the semiconductor die 115-1 as part of a semiconductor wafer held by a thermal chuck of a probing tool.

In some implementations, the protective fill structure 150 prevents a contaminant from gathering and bridging within the probe card substrate 705. Additionally, or alternatively, the protective fill structure 150 may insulate the ends of the conductive structures 335-1 and 335-2 to reduce a likelihood of ESD damage within the probe card substrate 705. Additionally, or alternatively, the protective fill structure 150 may protect the end of the conductive structure from oxidation and/or corrosion to reduce a likelihood of circuitry defects 335-1 and 335-2 within the probe card substrate 705. Additionally, or alternatively, the protective fill structure 150 may increase a rigidity of the probe card substrate 705 to reduce a likelihood of a flexure of the probe card substrate 705 that causes cracking of electrical traces or dielectric layers within the probe card substrate 705.

In this way, a productivity of the probe test system using the probe card substrate 705 may be increased relative to another probe test system not using the probe card substrate 705 (e.g., a downtime of the probe test system due to repair of the probe card substrate 705 may be reduced). Increasing the productivity of the probe test system may reduce an amount of resources required to fabricate a volume of the semiconductor die 115-1 (e.g., reduce an install base of the probe test system, manpower, and/or supporting computing resources).

As shown in FIG. 7B, in some implementations, the test interface substrate includes a burn-in board substrate 715 including the protective fill structure 150. In some implementations, a burn-in socket 720 (e.g., a temporary fixture for a semiconductor assembly, such as the apparatus 100) is communicatively coupled to the burn-in board substrate 715. The burn-in socket 720 may be communicatively coupled to the conductive structure 335-1 and 335-2 using one or more vertical interconnect access (via) structures 405 and/or one or more connection structures 410, among other examples.

In some implementations, the burn-in board substrate 715 may be communicatively coupled to a burn-in system to test a reliability of a semiconductor device assembly (e.g., the apparatus 100 including the integrated circuits 105-1 and 105-2) that is inserted into the burn-in socket 720. In some implementations, testing the reliability of the semiconductor device assembly may include inserting the burn-in board substrate 715 (including the apparatus 100 into the burn-in socket) into a burn-in chamber to test the apparatus 100 at an elevated temperature and/or an elevated voltage for an extended period of time.

Including the protective fill structure 150 in the burn-in board substrate 715 may increase a quantity of operable burn-in sockets (e.g., a quantity of the burn-in socket 720) coupled to the burn-in board substrate 715 due to a reduction in defects within the burn-in board substrate 715. For example, and in some implementations, the protective fill structure 150 prevents a contaminant from gathering and bridging within the burn-in board substrate 715. Additionally, or alternatively, the protective fill structure 150 may insulate the ends of the conductive structures 335-1 and 335-2 to reduce a likelihood of ESD damage within the burn-in board substrate 715. Additionally, or alternatively, the protective fill structure 150 may protect the end of the conductive structures 335-1 and 335-2 from oxidation and/or corrosion to reduce a likelihood of circuitry defects within the burn-in board substrate 715. Additionally, or alternatively, the protective fill structure 150 may increase a rigidity of the burn-in board substrate 715 to reduce a likelihood of a flexure of the burn-in board substrate 715 that causes cracking of electrical traces or dielectric layers within the burn-in board substrate 715.

In this way, a productivity of the burn-in test system using the burn-in board substrate 715 may be increased relative to another burn-in test system not using the burn-in board substrate 715 (e.g., an overall equipment efficiency (OEE) of the burn-in test system may increase due to an increase in operable burn-in sockets 720, among other examples). Increasing the productivity of the burn-in test system may reduce an amount of resources required to fabricate a volume of the apparatus 100 (e.g., reduce an install base of the burn-in test system, manpower, and/or supporting computing resources, among other examples).

As indicated above, FIGS. 7A and 7B are provided as an example. Other examples may differ from what is described with regard to FIGS. 7A and 7B.

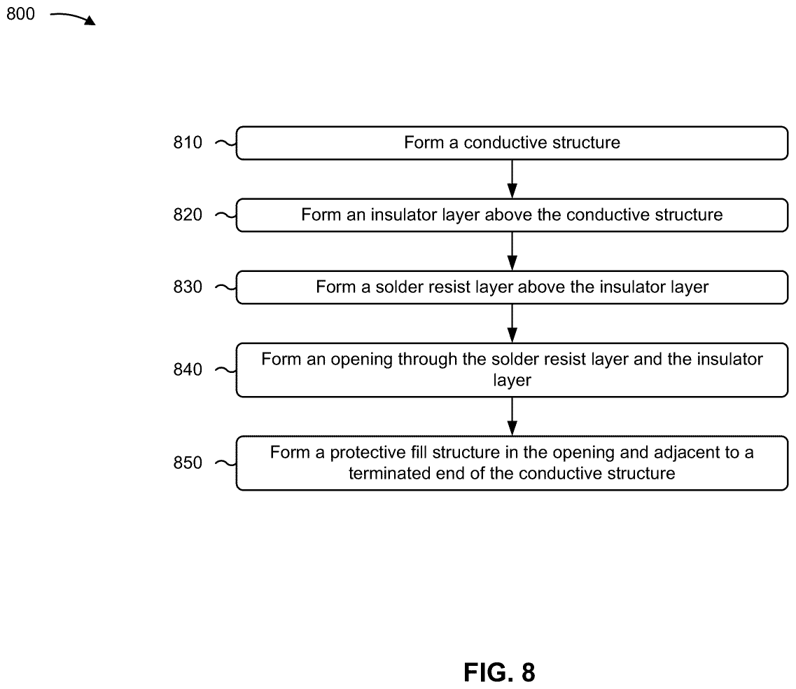

FIG. 8 is a flowchart of an example method 800 of forming a substrate including a protective fill structure. In some implementations, one or more process blocks of FIG. 8 may be performed by various semiconductor manufacturing equipment.

As shown in FIG. 8, the method 800 may include forming a conductive structure (block 810). As further shown in FIG. 8, the method 800 may include forming an insulator layer above the conductive structure (block 820). As further shown in FIG. 8, the method 800 may include forming a solder resist layer above the insulator layer (block 830). As further shown in FIG. 8, the method 800 may include forming an opening through the solder resist layer and the insulator layer (block 840). As further shown in FIG. 8, the method 800 may include forming a protective fill structure in the opening and adjacent to an end of the conductive structure (block 850).

The method 800 may include additional aspects, such as any single aspect or any combination of aspects described below and/or in connection with one or more other methods described elsewhere herein.

In a first aspect, forming the protective fill structure in the opening and adjacent to the end of the conductive structure comprises forming an amount of the protective fill structure that covers the end of the conductive structure.

In a second aspect, alone or in combination with the first aspect, forming the opening through the solder resist layer and the insulator layer comprises performing an etch-back operation to form the opening.

In a third aspect, alone or in combination with one or more of the first and second aspects, performing the etch-back operation comprises forming a terminated end of the conductive structure.

In a fourth aspect, alone or in combination with one or more of the first through third aspects, forming the protective fill structure comprises performing a coupon plugging operation, reflowing the solder resist layer, dispensing and curing a fill material, or screen printing the fill material.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the substrate 110 including the protective fill structure 150, an integrated assembly that includes the substrate 110 including the protective fill structure 150, any part described herein including the substrate 110 including protective fill structure 150, and/or any part described herein of an integrated assembly that includes the protective fill structure 150. For example, the method 800 may include forming one or more of the apparatus 100 and/or the memory device 200. Additionally, or alternatively, techniques described in the method 800 may be used in forming the circuit board 125, the substrate 220, the probe card substrate 705, and/or the burn-in board substrate 715.

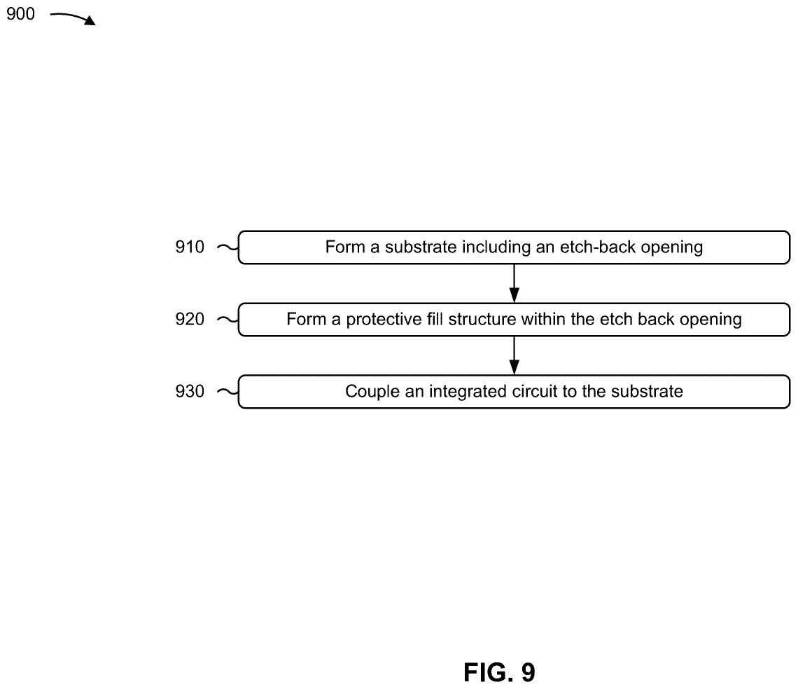

FIG. 9 is a flowchart of an example method 900 of forming an integrated assembly or apparatus including a substrate having a protective fill structure. In some implementations, one or more process blocks of FIG. 9 may be performed by various semiconductor manufacturing equipment.

As shown in FIG. 9, the method 900 may include forming a substrate including an etch-back opening (block 910). For example, the method 900 may include forming the substrate 110 including the isolation region 325 (e.g., an etch-back opening) as described herein.

As further shown in FIG. 9, the method 900 may include forming a protective fill structure within the etch-back opening (block 920). For example, the method 900 may include forming the fill structure 150 within the isolation region 325 (e.g., the etch-back opening) as described herein.

As further shown in FIG. 9, the method 900 may include coupling an integrated circuit to the substrate (block 930). For example, the method 900 may include coupling the integrated circuit 105-1 to the substrate 110 as described herein.

The method 900 may include additional aspects, such as any single aspect or any combination of aspects described below and/or in connection with one or more other methods described elsewhere herein.

In some implementations, the method 900 includes performing one or more additional operations. For example, the method 900 may include coupling the integrated circuit 105-2 to the substrate 110 as part of forming the apparatus 100 described herein. Additionally, or alternatively, the method 900 may include coupling the substrate 110 to the circuit board 125 (e.g., via the solder balls 140) as part of forming the apparatus 100 described herein. Additionally, or alternatively, the method 900 may include encapsulating integrated circuit 105 with the casing 120 as part of forming the apparatus herein. In these ways, the method 900 may include forming the apparatus 100 described herein.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming an integrated assembly that includes the substrate 110 including the protective fill structure 150, any part described herein including the substrate 110 including protective fill structure 150, and/or any part described herein of an integrated assembly that includes the protective fill structure 150. For example, the method 900 may include forming the memory device 200. Additionally, or alternatively, techniques described in the method 900 may be used in forming the circuit board 125, the substrate 220, the probe card substrate 705, and/or the burn-in board substrate 715.

In some implementations, a semiconductor device assembly includes a substrate including: an insulator layer; a circuit layer below the insulator layer and including: a circuit structure; an isolation region adjacent to the circuit structure; and a protective fill structure in the isolation region; and a semiconductor die electrically connected to the substrate via a plurality of electrical connections.

In some implementations, a substrate assembly includes a top insulator layer; a conductive layer below the top insulator layer and comprising: an end of a conductive structure; a bottom insulator layer below the conductive layer; and a protective fill structure adjacent to the end of the conductive structure and passing at least partially through the top insulator layer to the bottom insulator layer.

In some implementations, a method includes forming a conductive structure; forming an insulator layer above the conductive structure; forming a solder resist layer above the insulator layer; forming an opening through the solder resist layer and the insulator layer; and forming a protective fill structure in the opening and adjacent to an end of the conductive structure.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one.” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate comprising:
an insulator layer;
a circuit layer below the insulator layer and comprising:
a circuit structure;
an isolation region adjacent to the circuit structure; and
a protective fill structure in the isolation region; and
a semiconductor die electrically connected to the substrate via a plurality of electrical connections.

2. The semiconductor device assembly of claim 1, wherein the protective fill structure passes at least partially through the insulator layer.

3. The semiconductor device assembly of claim 1, wherein the protective fill structure passes entirely through the insulator layer.

4. The semiconductor device assembly of claim 1, wherein the circuit structure corresponds to a ground plane structure, and
wherein the protective fill structure is configured to protect an end of the ground plane structure or an end of a power plane structure from corrosion or oxidation.

5. The semiconductor device assembly of claim 1, wherein the circuit structure corresponds to a data transmission structure, and
wherein the protective fill structure is configured to protect an end of the data transmission structure or an end of or a clocking structure from corrosion or oxidation.

6. The semiconductor device assembly of claim 1, wherein the circuit structure is a first circuit structure, and wherein the semiconductor device assembly further comprises:
a second circuit structure,
wherein the protective fill structure is between a first end of the first circuit structure and a second end of the second circuit structure.

7. The semiconductor device assembly of claim 1, wherein the protective fill structure is directly below the semiconductor die.

8. The semiconductor device assembly of claim 1, wherein the protective fill structure is adjacent to the semiconductor die.

9. The semiconductor device assembly of claim 1, wherein the protective fill structure comprises a polymer material, and
wherein the polymer material is included in an epoxy material or a solder resist material.

10. The semiconductor device assembly of claim 1, wherein the semiconductor die is a non-volatile memory semiconductor die or a volatile memory semiconductor die, and wherein the semiconductor device assembly further comprises:
a controller communicatively coupled to the semiconductor die via the substrate.

11. A substrate assembly, comprising:
a top insulator layer;
a conductive layer below the top insulator layer and comprising:
an end of a conductive structure;
a bottom insulator layer below the conductive layer; and
a protective fill structure adjacent to the end of the conductive structure and passing at least partially through the top insulator layer to the bottom insulator layer.

12. The substrate assembly of claim 11, wherein the protective fill structure passes entirely through the top insulator layer.

13. The substrate assembly of claim 11, wherein the conductive structure is a first conductive structure, the end of the conductive structure is a first end of the first conductive structure, and wherein the conductive layer below the top insulator layer further comprises:
a second end of a second conductive structure, and
wherein the protective fill structure is between the first end of the first conductive structure and the second end of the second conductive structure.

14. The substrate assembly of claim 13, wherein the protective fill structure is configured to electrically isolate the first end of the first conductive structure and the second end of the second conductive structure.

15. The substrate assembly of claim 11, further comprising:
a solder resist layer above the top insulator layer, and
wherein the protective fill structure passes at least partially through the solder resist layer.

16. The substrate assembly of claim 15, wherein the protective fill structure passes entirely through the solder resist layer.

17. The substrate assembly of claim 11, wherein the protective fill structure is configured to satisfy a rigidity threshold of the substrate assembly.

18. A method, comprising:
forming a conductive structure;
forming an insulator layer above the conductive structure;
forming a solder resist layer above the insulator layer;
forming an opening through the solder resist layer and the insulator layer; and
forming a protective fill structure in the opening and adjacent to an end of the conductive structure.

19. The method of claim 18, wherein forming the protective fill structure in the opening and adjacent to the end of the conductive structure comprises:
forming an amount of the protective fill structure that covers the end of the conductive structure.

20. The method of claim 18, wherein forming the opening through the solder resist layer and the insulator layer comprises:
performing an etch-back operation to form the opening.
